(19) United States
(12) Patent Application Publication
(10) Pub. No.: US 2024/0387571 A1
(43) Pub. Date: Nov. 21, 2024

(54) PHOTOELECTRIC CONVERSION DEVICE AND EQUIPMENT

(71) Applicant: CANON KABUSHIKI KAISHA, Tokyo (JP)

(72) Inventors: YUKI KITAZAWA, Kanagawa (JP); TATSUYA MURAO, Kanagawa (JP); YASUSHI KOYAMA, Kanagawa (JP); TAKAHIRO YAJIMA, Kanagawa (JP); AYMAN TAREK ABDELGHAFAR, Tokyo (JP)

(21) Appl. No.: 18/661,898

(22) Filed: May 13, 2024

(30) Foreign Application Priority Data
May 19, 2023 (JP) 2023-083186

(51) Int. Cl. H01L 27/146

(52) U.S. Cl. CPC H01L 27/1461; H01L 27/14623; H01L 27/14627; H01L 27/1463; H01L 27/14636; H01L 27/1465

(57) ABSTRACT

A photoelectric conversion device in which a plurality of pixels are arranged in a semiconductor layer having a first principal surface and a second principal surface is provided. Each of the plurality of pixels includes: an avalanche photodiode arranged in the semiconductor layer; and a Schottky barrier diode constituted by the semiconductor layer and an electrode pattern in contact with the second principal surface. In an orthogonal projection to the second principal surface, the second principal surface has a region overlapping the avalanche photodiode, and the region includes a first region in contact with the electrode pattern and a second region in contact with an insulating layer.

### BACKGROUND OF THE INVENTION

### Field of the Invention

The present invention relates to a photoelectric conversion device and equipment.

### Description of the Related Art

There is known a photoelectric conversion element using an avalanche photodiode (APD) that causes avalanche multiplication capable of detecting faint light of a single photon level. Japanese Patent Laid-Open No. 2018-201005 discloses a photodetector in which a sensor chip constituted by arraying APDs in a pixel region, and a logic chip including circuits for processing a signal output from the APD and supplying power to the APD are stacked. Japanese Patent Laid-Open No. 2018-201005 also discloses formation of APDs on a silicon substrate.

Silicon has a low absorption coefficient on the long wavelength side and becomes poor in sensitivity to the shortwave infrared (SWIR) range or the like.

### SUMMARY OF THE INVENTION

Some embodiments of the present invention provide a technique advantageous for improving the sensitivity to the long wavelength range.

According to some embodiments, a photoelectric conversion device in which a plurality of pixels are arranged in a semiconductor layer having a first principal surface and a second principal surface, wherein each of the plurality of pixels comprises: an avalanche photodiode arranged in the semiconductor layer; and a Schottky barrier diode constituted by the semiconductor layer and an electrode pattern in contact with the second principal surface, in an orthogonal projection to the second principal surface, the second principal surface has a region overlapping the avalanche photodiode, and the region includes a first region in contact with the electrode pattern and a second region in contact with an insulating layer, is provided.

According to some other embodiments, a photoelectric conversion device in which a plurality of pixels are arranged in a semiconductor layer having a first principal surface and a second principal surface, wherein each of the plurality of pixels comprises: an avalanche photodiode arranged in the semiconductor layer; and a Schottky barrier diode constituted by the semiconductor layer and an electrode pattern in contact with the second principal surface, a plurality of recesses in which the electrode pattern is buried are provided on the second principal surface, in an orthogonal projection to the second principal surface, the second principal surface has a region overlapping the avalanche photodiode, and the region includes a first region where the plurality of recesses are arranged, and a second region where the plurality of recesses are not arranged, is provided.

According to still other embodiments, a photoelectric conversion device in which a plurality of pixels are arranged in a semiconductor layer having a first principal surface and a second principal surface, wherein each of the plurality of pixels comprises: an avalanche photodiode arranged in the semiconductor layer; and a Schottky barrier diode constituted by the semiconductor layer and an electrode pattern in contact with the second principal surface to cover the second principal surface, and the second principal surface has a periodic concave-convex structure, is provided.

Further features of the present invention will become apparent from the following description of exemplary embodiments (with reference to the attached drawings).

### BRIEF DESCRIPTION OF THE DRAWINGS

FIG. 1 is a view showing an arrangement example of a photoelectric conversion device according to an embodiment;

FIG. 2 is a view showing an arrangement example of the pixel array of the photoelectric conversion device in FIG. 1;

FIG. 3 is a block diagram showing an arrangement example of the photoelectric conversion device in FIG. 1;

FIG. 4 is a circuit diagram showing an arrangement example of the pixel of the photoelectric conversion device in FIG. 1;

FIGS. 5A, 5B and 5C are a view and a graph respectively for explaining an operation example of the pixel of the photoelectric conversion device in FIG. 1;

FIG. 6 is a plan view showing an arrangement example of the pixel of the photoelectric conversion device in FIG. 1;

FIG. 7 is a sectional view showing the arrangement example of the pixel in FIG. 6;

FIGS. 8A to 8D are plan views showing arrangement examples of the pixel of the photoelectric conversion device in FIG. 1;

FIG. 9 is a plan view showing an arrangement example of the pixel of the photoelectric conversion device in FIG. 1;

FIG. 10 is a sectional view showing the arrangement example of the pixel in FIG. 9;

FIG. 11 is a sectional view showing the arrangement example of the pixel in FIG. 9;

FIG. 12 is a sectional view showing an arrangement example of the pixel of the photoelectric conversion device in FIG. 1;

FIG. 13 is a graph showing the characteristic of the pixel in FIG. 12;

FIG. 14 is a view for explaining the pillar structure of the pixel in FIG. 12;

FIG. 15 is a graph showing the characteristic of the pixel in FIG. 12; and

FIG. 16 is a schematic view showing an arrangement example of a camera incorporating the photoelectric conversion device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

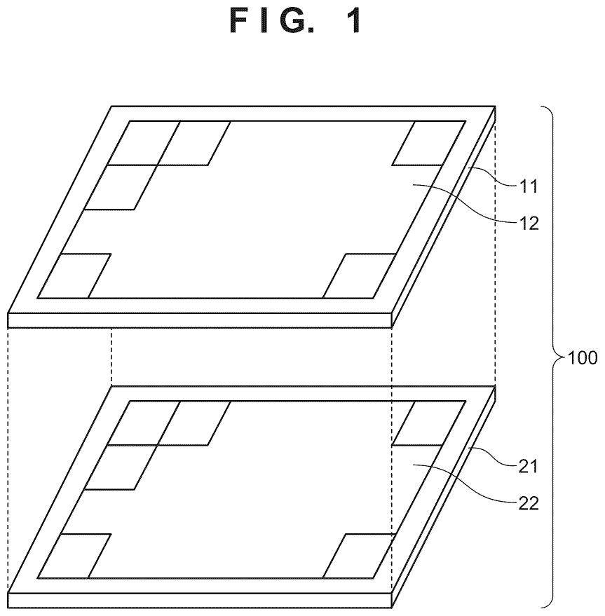

First, an arrangement common to embodiments to be described later will be explained with reference to FIG. 1 to FIGS. 5A to 5C. FIG. 1 is a view showing an arrangement example of a photoelectric conversion device 100. The photoelectric conversion device 100 can be constituted by stacking two boards, that is, a sensor board 11 and a circuit board 21 and electrically connecting them. In other words, the photoelectric conversion device 100 can be a stacked device. On the sensor board 11, a semiconductor layer 301 in which a plurality of pixels 101 are arranged, a wiring structure 302, and the like are arranged, which will be described later. On the circuit board 21, a semiconductor layer 304 including circuits such as signal processing circuits 103, a wiring structure 305, and the like are arranged, which will be described later. The photoelectric conversion device 100 can be constituted by stacking the semiconductor layer 304 of the circuit board 21, the wiring structure 305 of the circuit board 21, the wiring structure 302 of the sensor board 11, and the semiconductor layer 301 of the sensor board 11 in this order. The photoelectric conversion device 100 can be a so-called backside illumination photoelectric conversion device in which light enters from a principal surface 393 of the semiconductor layer 301 of the sensor board 11. A pixel region 12 including the pixels 101 is arranged on the sensor board 11. A circuit region 22 where a signal detected in the pixel region 12 is processed is arranged on the circuit board 21.

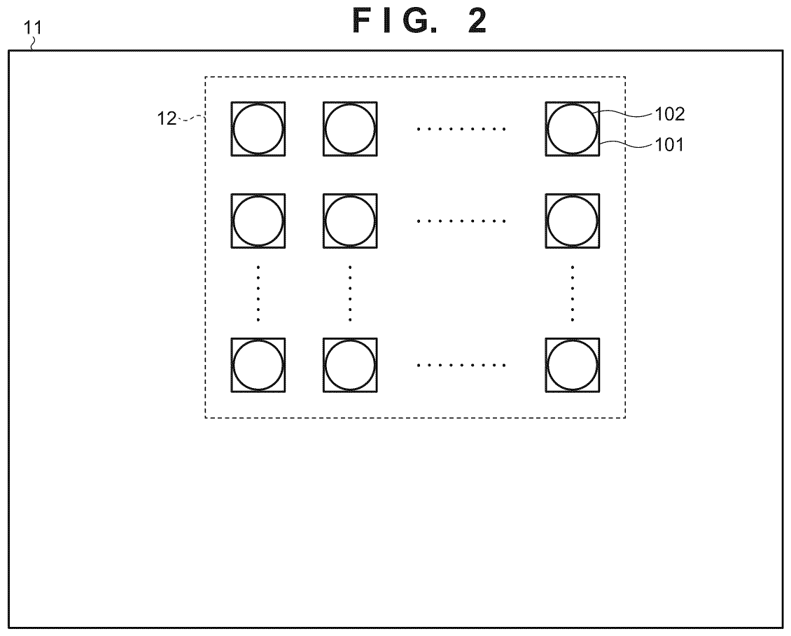

FIG. 2 is a view showing an arrangement example of the sensor board 11. The pixels 101 each having a photoelectric conversion element 102 including an avalanche photodiode (to be sometimes referred to as an APD hereinafter) are arrayed two-dimensionally when viewed from the top, forming the pixel region 12. The pixel 101 is typically a pixel for generating an image, but when it is used in a Time of Flight (ToF) distance measurement device, may not always generate an image. That is, the pixel 101 may be configured to measure the time when light arrives and the quantity of light. Here, “viewed from the top” means viewed from the direction of the normal to the light incident surface of the semiconductor layer 301 (to be described later). The pixel 101 can also be referred to as a unit cell, and the pixel region 12 can also be referred to as a unit cell array.

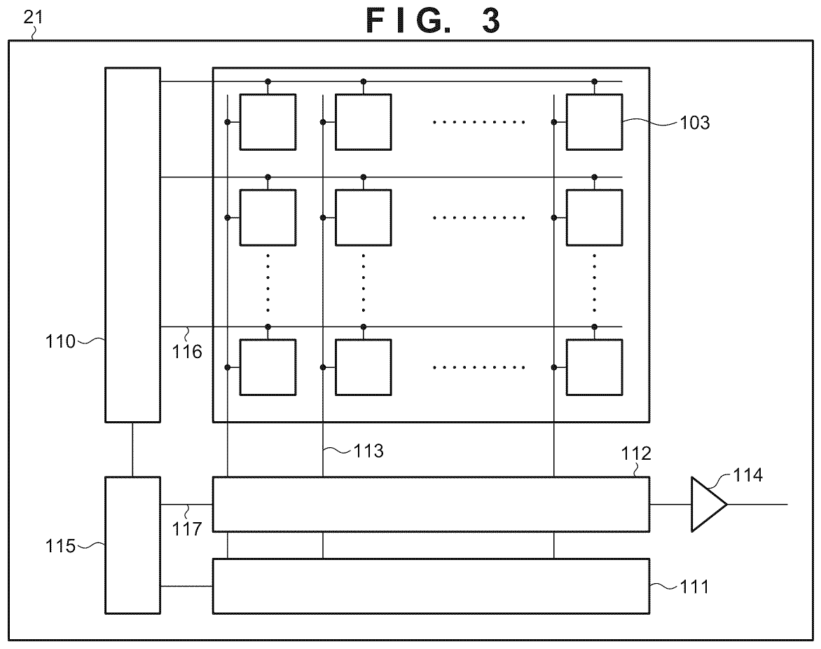

FIG. 3 is a block diagram showing an arrangement example of the circuit board 21. The circuit board 21 includes the signal processing circuits 103 that process charges photoelectrically converted by the photoelectric conversion elements 102 shown in FIG. 2, a readout circuit 112, a control pulse generation circuit 115, a horizontal scanning circuit 111, signal lines 113, a vertical scanning circuit 110, and the like. The signal processing circuits 103 shown in FIG. 3 may be arranged in correspondence with the respective pixels 101 shown in FIG. 2. In this case, the pixels 101 (photoelectric conversion elements 102) and the signal processing circuits 103 may be electrically connected via connection lines provided for the respective pixels 101. A concrete arrangement of a connection portion that electrically connects the pixel 101 (photoelectric conversion element 102) and the signal processing circuit 103 is, for example, a structure in which conductor patterns of copper or the like are bonded, a structure using a micro-bump, or a structure in which a through electrode is provided.

The vertical scanning circuit 110 receives a control pulse supplied from the control pulse generation circuit 115, and supplies a control pulse to the respective pixels 101 via a plurality of control signal lines 116. A logic circuit such as a shift register or an address decoder can be used for the vertical scanning circuit 110.

A signal output from the pixel 101 is processed by the signal processing circuit 103. A counter, a memory, and the like can be provided in the signal processing circuit 103. The memory can hold, as a digital value, a count value obtained by counting by the counter.

The horizontal scanning circuit 111 inputs, to the signal processing circuits 103, a control pulse for sequentially selecting respective columns in order to read out signals from the memories of the signal processing circuits 103 corresponding to the respective pixels 101 in which digital signals are held. As for a selected column, a signal is output to the signal line 113 from the signal processing circuit 103 corresponding to the pixel 101 selected by the vertical scanning circuit 110. The signal output to the signal line 113 is output via an output circuit 114 to a recording unit or a signal processing unit outside the photoelectric conversion device 100.

The array of the pixels 101 in the pixel region 12 shown in FIG. 2 is not limited to a two-dimensional array. The pixels 101 may be arranged one-dimensionally. The function of the signal processing circuit 103 need not always be provided one by one in all the pixels 101 (photoelectric conversion elements 102). For example, one signal processing circuit 103 may be shared between the plurality of pixels 101 (photoelectric conversion elements 102) to sequentially perform signal processing.

As shown in FIGS. 2 and 3, the signal processing circuits 103 can be arranged in a region overlapping the pixel region 12 in an orthogonal projection to the pixel region 12. The vertical scanning circuit 110, the horizontal scanning circuit 111, the readout circuit 112, the output circuit 114, the control pulse generation circuit 115, and the like can be so arranged as to overlap a gap between the end of the sensor board 11 and that of the pixel region 12. In other words, the sensor board 11 has the pixel region 12 and a non-pixel region arranged around the pixel region 12. In this case, the vertical scanning circuit 110, the horizontal scanning circuit 111, the readout circuit 112, the output circuit 114, and the control pulse generation circuit 115 can be arranged in a region overlapping the non-pixel region.

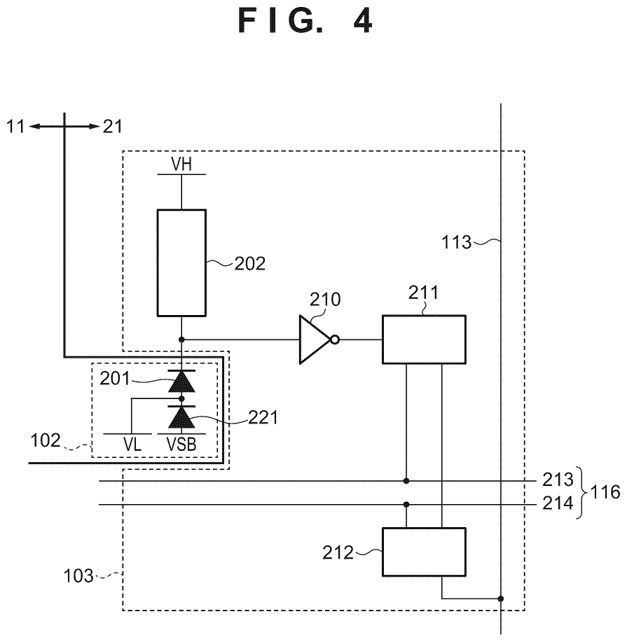

FIG. 4 shows an example of a block diagram including an equivalent circuit when paying attention to one pixel 101 (photoelectric conversion element 102). In FIG. 4, the photoelectric conversion element 102 including an APD 201 and a Schottky barrier diode 221 (to be sometimes referred to as an SBD 221 hereinafter) series-connected to the APD 201 is provided on the sensor board 11, and the remaining components are provided on the circuit board 21. However, the present invention is not limited to this, and some components arranged on the circuit board 21 shown in FIG. 4 may be arranged on the sensor board 11. For example, the configuration of the sensor board 11 and circuit board 21 may be arranged on one board, instead of the stacked structure. A solid line between the sensor board 11 and the circuit board 21 shown in FIG. 4 is a boundary between the sensor board 11 and the circuit board 21 and indicates the position of a joint portion. In this embodiment, one signal processing circuit 103 corresponds to one photoelectric conversion element 102.

The SBD 221 has a function of generating a charge pair corresponding to incident light by photoelectric conversion. The SBD 221 is constituted by an electrode pattern 321 functioning as a Schottky electrode, and the semiconductor layer 301 (a semiconductor region 306), details of which will be described later. More specifically, the SBD 221 is constituted including a Schottky barrier formed on a joint surface (that can coincide with the principal surface 393 of the semiconductor layer 301) between the electrode pattern 321 and the semiconductor layer 301, and a depletion region 322 formed near the Schottky barrier of the semiconductor layer 301. Photoelectric conversion includes two processes, that is, generation of a photocarrier by photoexcitation, and separation of the generated photocarrier. Photoexcitation occurs at a contact portion between a metal and a semiconductor, and separation of a photocarrier occurs in the internal field of a depletion layer region. To suppress recombination of a generated photocarrier, the semiconductor region 306 of the semiconductor layer 301 where the depletion region 322 is formed is a region of a low impurity concentration where a wide depletion region can be ensured. A potential VSB is supplied to the anode of the SBD 221, and a potential VL is supplied to the cathode. For example, the potential VSB is −31 V and the potential VL is −30 V.

The APD 201 generates a charge pair corresponding to incident light by photoelectric conversion. The potential VL is supplied to the anode of the APD 201. A potential VH higher than the potential VL supplied to the anode is supplied to the cathode of the APD 201. A reverse bias voltage is supplied to the anode and the cathode so that the APD 201 performs an avalanche multiplication operation. In a state in which such a reverse bias voltage is supplied, charges generated by incident light cause avalanche multiplication, generating an avalanche current.

In a case where the reverse bias voltage is supplied to the APD 201, there are a Geiger mode in which the APD 201 is operated by a potential difference (voltage) between the anode and the cathode larger than a breakdown voltage, and a linear mode in which the APD 201 is operated by a potential difference between the anode and the cathode larger that is near the breakdown voltage or equal to or lower than it. An APD operated in the Geiger mode can be called a Single Photon Avalanche Diode (SPAD). For example, the potential VL is −30 V, as described above, and the potential VH is 1 V. The APD 201 may be operated in the linear mode or the Geiger mode.

In the following description, the anode of the avalanche photodiode (APD) is set at a fixed potential and a signal is extracted from the cathode. Therefore, a semiconductor region of the first conductivity type where a charge of the same polarity as that of a signal charge serves as a majority carrier is an n-type semiconductor region, and a semiconductor region of the second conductivity type where a charge of a polarity different from that of a signal charge serves as a majority carrier is a p-type semiconductor region. However, this disclosure is established even in a case where the cathode of the APD is set at a fixed potential and a signal is extracted from the anode. In this case, a semiconductor region of the first conductivity type where a charge of the same polarity as that of a signal charge serves as a majority carrier is a p-type semiconductor region, and a semiconductor region of the second conductivity type where a charge of a polarity different from that of a signal charge serves as a majority carrier is an n-type semiconductor region. A case where one node of the APD is set at a fixed potential will be explained, but the potentials of two nodes may vary.

A quench element 202 is connected between a power supply that supplies the potential VH, and the APD 201. The quench element 202 functions as a load circuit (quench circuit) at the time of signal multiplication by avalanche multiplication, and operates to suppress a voltage supplied to the APD 201 and suppress avalanche multiplication (quench operation). The quench element 202 also operates to return the voltage supplied to the APD 201 to a voltage (VH-VL) by supplying a current by an amount corresponding to a voltage drop caused by the quench operation (recharge operation).

The signal processing circuit 103 can include a waveform shaping circuit 210, a counter circuit 211, a selection circuit 212, and the quench element 202. In this specification, the signal processing circuit 103 suffices to include any of the waveform shaping circuit 210, the counter circuit 211, and the selection circuit 212.

The waveform shaping circuit 210 shapes a potential change of the cathode of the APD 201 that is obtained at the time of photon detection, and outputs a pulse signal. As the waveform shaping circuit 210, for example, an inverter circuit is used. In the arrangement shown in FIG. 4, the use of one inverter as the waveform shaping circuit 210 is exemplified. However, the present invention is not limited to this, and a circuit constituted by series-connecting a plurality of inverters may be used as the waveform shaping circuit 210 or another circuit having the waveform shaping effect may be used.

The counter circuit 211 counts pulse signals output from the waveform shaping circuit 210 and holds the count value. When a control pulse pRES is supplied via a driving line 213, the signal held by the counter circuit 211 is reset.

The selection circuit 212 receives a control pulse pSEL from the vertical scanning circuit 110 shown in FIG. 3 via a driving line 214 shown in FIG. 4, and switches electrical connection/disconnection between the counter circuit 211 and the signal line 113. The selection circuit 212 includes, for example, a buffer circuit for outputting a signal.

A switching element such as a transistor may be interposed between the quench element 202 and the APD 201 or between the photoelectric conversion element 102 and the signal processing circuit 103 so that electrical connection can be switched. Similarly, supply of the potential VH or potential VL to the photoelectric conversion element 102 may be electrically switchable using a switching element such as a transistor.

In this embodiment, the counter circuit 211 is arranged in the signal processing circuit 103. However, the present invention is not limited to this, and a Time-to-Digital Converter (TDC) and a memory may be used instead of the counter circuit 211 so that the photoelectric conversion device 100 obtains a pulse detection timing. In this case, the generation timing of a pulse signal output from the waveform shaping circuit 210 is converted into a digital signal by the TDC. The TDC receives a control pulse pREF (reference signal) from the vertical scanning circuit 110 via a driving line for measurement of the timing of the pulse signal. By using the control pulse pREF as a reference, the TDC obtains, as a digital signal, a signal when the input timing of a signal output from each pixel 101 via the waveform shaping circuit 210 is regarded as a relative time.

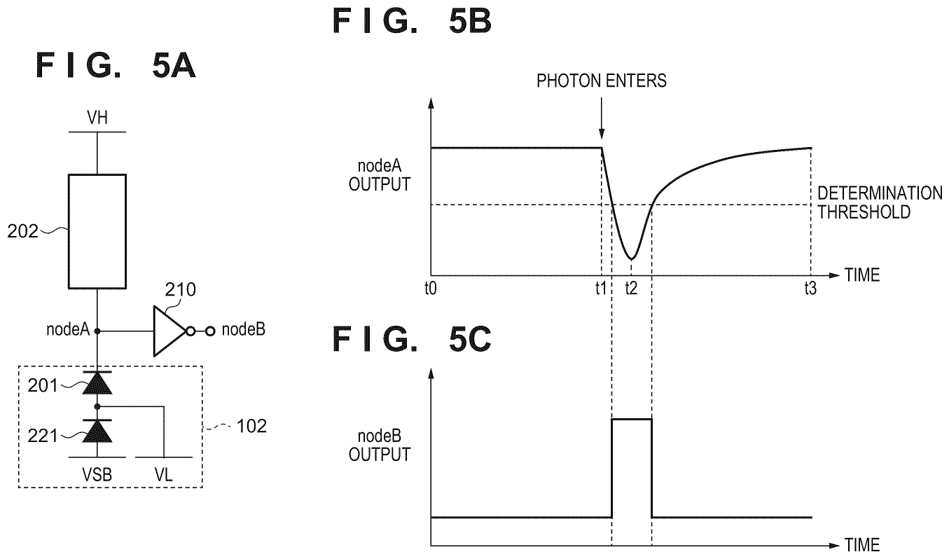

FIGS. 5A to 5C are a view and a graph, respectively, schematically showing the relationship between the operations of the APD 201 and SBD 221 and an output signal. FIG. 5A is a view showing an excerpt of the APD 201, SBD 221, quench element 202, and waveform shaping circuit 210 shown in FIG. 4. Here, the input side of the waveform shaping circuit 210 is a node A and its output side is a node B. FIGS. 5B and 5C show waveform changes at the node A and the node B.

From time t0 to time t1, a potential difference (voltage) of the potential VH—the potential VSB is applied to the photoelectric conversion element 102 constituted by the APD 201 and the SBD 221. A potential difference of the potential VH—the potential VL is applied to the APD 201, and a potential difference of the potential VL—the potential VSB is applied to the SBD 221. When a photon enters at time t1, the APD 201 or the SBD 221 generates a charge pair corresponding to the incident light by photoelectric conversion. The generated charge pair causes avalanche multiplication in the APD 201, an avalanche multiplication current flows into the quench element 202, and the potential of the node A drops. When the potential drop amount further increases and the potential difference applied to the APD 201 decreases, the avalanche multiplication of the APD 201 stops and the potential level of the node A does not drop any more from a predetermined value. From time t2 to time t3, a current compensating for the potential drop flows to the node A from a power supply line for supplying the potential VL. At time t3, the node A is statically determined at the original potential level. A portion at which the output waveform exceeds a given threshold at the node A is waveform-shaped by the waveform shaping circuit 210 and output as a signal to the node B.

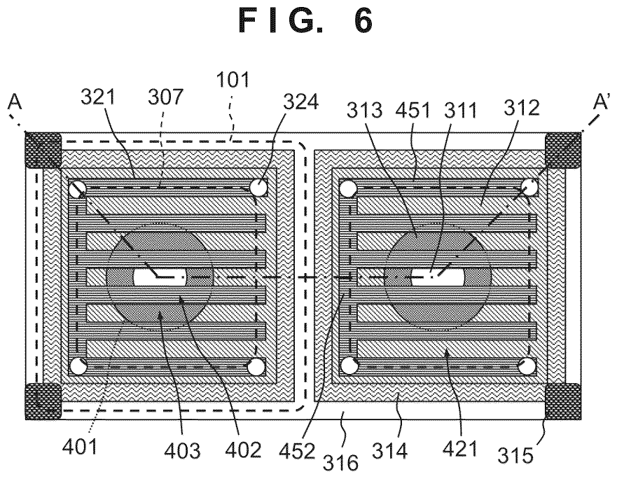

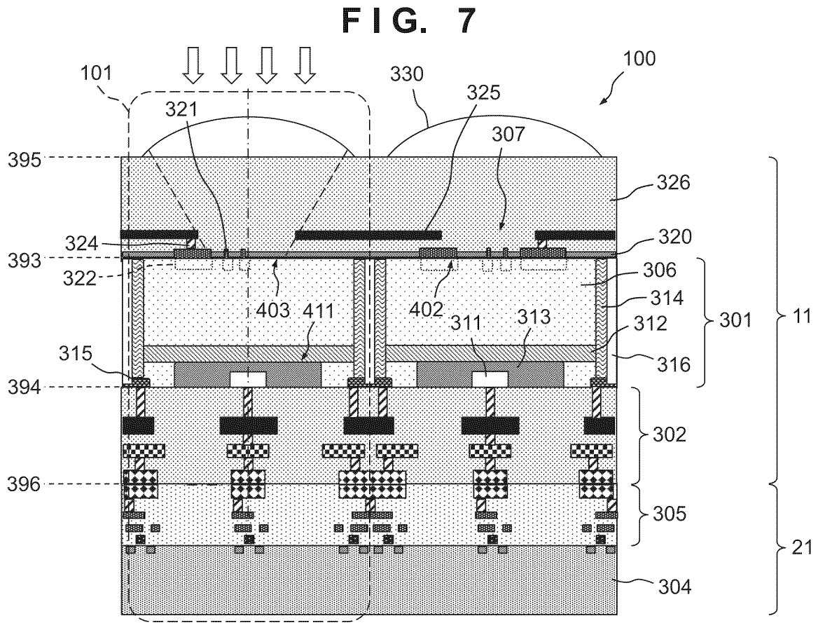

Next, the arrangement of the pixel 101 arranged in the photoelectric conversion device 100 will be explained in detail. FIG. 6 is a plan view (orthogonal projection view) showing the arrangement of the pixel 101 arranged in the pixel region 12. FIG. 7 is a sectional view between A-A′ in FIG. 6. As described above, the photoelectric conversion device 100 has a stacked structure in which the sensor board 11 and the circuit board 21 are stacked via a joint surface 396.

The sensor board 11 includes the semiconductor layer 301 having the principal surface 393 and a principal surface 394, the wiring structure 302, a sealing layer 326, and microlenses 330. The wiring structure 302 is interposed between the principal surface 394 of the semiconductor layer 301 and the joint surface 396. The sealing layer 326 is interposed between the principal surface 393 of the semiconductor layer 301 and a light incident surface 395 on which the microlenses 330 are arranged. The circuit board 21 includes the semiconductor layer 304 in which circuits such as the signal processing circuit 103 are arranged, and the wiring structure 305 interposed between the semiconductor layer 304 and the joint surface 396.

In the semiconductor layer 301, each pixel 101 includes a semiconductor region 311 of the first conductivity type, a semiconductor region 312 of the second conductivity type, a semiconductor region 313 of the first conductivity type, a semiconductor region 314 of the second conductivity type, a semiconductor region 315 of the second conductivity type, and the semiconductor region 306. The respective pixels 101 are isolated by trench structures 316. The semiconductor regions 306 and 311 to 315 of the semiconductor layer 301 are regions in each of which an impurity corresponding to the conductivity type is doped. Hence, the semiconductor layer 301 can also be called a silicon layer.

In the above-described APD 201, the semiconductor region 313 of the first conductivity type and the semiconductor region 312 of the second conductivity type are arranged, and the semiconductor regions 313 and 312 form a p-n junction. As shown in FIG. 7, the surface on which the p-n junction is formed is sometimes called a p-n junction surface 411. A predetermined reverse bias voltage is applied between the semiconductor region 313 and the semiconductor region 312, causing avalanche multiplication upon incidence of light. In a region between the semiconductor region 312 and the principal surface 393 of the semiconductor layer 301, the semiconductor region 315 (for example, a p-type epitaxial layer or an n-type epitaxial layer) of a low impurity concentration is arranged in contact with the semiconductor region 312. By applying a reverse bias between the semiconductor regions 311 and 313 and the semiconductor region 312, the depletion layer widens toward the principal surface 393 of the semiconductor layer 301.

On the principal surface 394 of the semiconductor layer 301, the APD 201 is electrically connected to a wiring pattern arranged in the wiring structure 302. The semiconductor region 311 can function as the cathode electrode of the APD 201. The semiconductor region 315 can function as the anode of the APD 201.

The above-described SBD 221 constituted by the semiconductor layer 301 (semiconductor region 306) and the electrode pattern 321 in contact with the principal surface 393 (semiconductor region 306) of the semiconductor layer 301 is arranged on the principal surface 393 of the semiconductor layer 301. Therefore, the photoelectric conversion device 100 according to the embodiment has an arrangement in which the APD 201 and the SBD 221 are series-connected in the direction of thickness of the semiconductor layer 301 via the depletion region 322 of the SBD 221 formed in the semiconductor region 306. As shown in FIG. 6, the SBD 221 may be arranged to overlap the APD 201 in an orthogonal projection to the principal surface 393 of the semiconductor layer 301.

A pinning layer 320 may be arranged between the principal surface 393 of the semiconductor layer 301 and the sealing layer 326. It can be said that the pinning layer 320 is arranged to seal the principal surface 393 of the semiconductor layer 301. By arranging the pinning layer 320 in contact with the principal surface 393 of the semiconductor layer 301, holes are induced near the principal surface 393 of the semiconductor layer 301 to suppress a dark current. For the pinning layer 320, an insulating film made of hafnium oxide, zirconium oxide, aluminum oxide, titanium oxide, tantalum oxide, or the like can be used.

An opening from which the principal surface 393 of the semiconductor layer 301 is exposed is formed in part of the pinning layer 320, and the electrode pattern 321 of the SBD 221 is arranged at the portion where the principal surface 393 of the semiconductor layer 301 is exposed. The electrode pattern 321 contacts the semiconductor region 306 constituting at least part of the principal surface 393 of the semiconductor layer 301, forming a Schottky junction. For the electrode pattern 321, a material that forms a Schottky junction with the semiconductor region 306 is selected. The electrode pattern 321 may be made of a metal, a conductive oxide, or a silicide.

At the Schottky junction, a Schottky barrier arising from a difference in work function between the semiconductor region 306 and the electrode pattern 321 is formed. The height of the Schottky barrier is often equal to or smaller than ½ of the bandgap (about 1.2 eV) of silicon constituting the semiconductor layer 301 because the impurity concentration of the semiconductor region 306 constituting the semiconductor layer 301 is low. Upon irradiation with light (wavelength of 0.8 to 30 μm) of the infrared wavelength range having energy exceeding the height of the Schottky barrier, generated charges (electrons or holes) climb up the Schottky barrier and reach the depletion region 322. Thus, the photoelectric conversion device 100 according to the embodiment can improve the sensitivity to the long wavelength range, which is low only with the APD 201 formed using silicon.

Examples of the material of the electrode pattern 321 constituting the SBD 221 are the following metal materials, silicides, and conductive metal oxides. As the metal materials, ytterbium (Yb), aluminum (Al), manganese (Mn), bismuth (Bi), tin (Sn), antimony (Sb), lead (Pb), hafnium (Hf), zirconia (Zr), silver (Ag), titanium (Ti), and the like can be used as materials sensitive in a wavelength band of 1,550 to 1,800 nm (0.7 to 0.8 eV). Also, nickel (Ni), iron (Fe), gold (Au), palladium (Pd), platinum (Pt), and the like can be used as materials sensitive in a wavelength band of 2,000 to 2,500 nm (0.5 to 0.6 eV). As the silicide (metal silicide) as a compound of silicon and a metal, yttrium silicide (YSi₂) can be used as a material sensitive in a wavelength of 1,550 nm (0.75 eV). Zirconium silicide (ZrSi₂), hafnium silicide (HfSi), nickel silicide (NiSi, NiSi₂), titanium silicide (TiSi₂), cobalt silicide (CoSi₂), manganese silicide (MnSi), and the like can be used as materials sensitive in a wavelength of 2,500 to 3,000 nm (0.4 to 0.5 eV). Iridium silicide (IrSi) and platinum silicide (PtSi, Pt₂Si) can be used as materials sensitive in a wavelength of 4,000 to 6,000 nm (0.2 to 0.3 eV).

A conductive metal oxide may be used for the electrode pattern 321. Examples of the metal oxide are indium tin oxide (ITO), indium zinc oxide (IZO), zinc oxide (ZnO), indium gallium zinc oxide (IGZO), tin oxide (SnO₂), titanium oxide (TiO₂), and molybdenum oxide (MoO₂).

In this embodiment, light entering the photoelectric conversion device 100 enters the principal surface 393 of the semiconductor layer 301 via the microlens 330. The incident light is photoelectrically converted near the interface of a Schottky junction constituted by the electrode pattern 321 and the semiconductor region 306, or in the semiconductor region 306 functioning as the light absorption layer of the APD 201, generating a photocarrier by photoexcitation. However, when most of the light entering the photoelectric conversion device 100 is reflected by the upper surface of the electrode pattern 321, the sensitivity of the photoelectric conversion device 100 decreases. To solve this, the electrode pattern 321 has slits 421, as shown in FIG. 6. With the slits 421, the principal surface 393 of the semiconductor layer 301 has a region 401 overlapping the APD 201 in an orthogonal projection to the principal surface 393. The region 401 includes a region 402 in contact with the electrode pattern 321, and a region 403 in contact with the pinning layer 320 serving as an insulating layer. It can be said that the slits 421 of the electrode pattern 321 constitute the region 403.

A region overlapping the APD 201 of the principal surface 393 of the semiconductor layer 301 is a region overlapping a region functioning as the APD 201 out of the semiconductor layer, such as the p-n junction surface 411 on which the semiconductor region 313 and the semiconductor region 312 contact each other, or a portion functioning as a light absorption layer out of the semiconductor region 306. For example, the region overlapping the APD 201 may be a region overlapping the p-n junction surface 411 in the orthogonal projection to the principal surface 393 of the semiconductor layer 301. The region 401 in FIG. 6 represents a region overlapping the p-n junction surface 411.

As shown in FIG. 6, in the orthogonal projection to the principal surface 393 of the semiconductor layer 301, the electrode pattern 321 may have a lateral direction in FIG. 6 as a longitudinal direction, and include a plurality of portions 451 arranged to align in a vertical direction intersecting the lateral direction, and a portion 452 arranged in the vertical direction so as to connect ends of the portions 451 to each other on one side in the lateral direction. The slits 421 are arranged between the respective portions 451. In the orthogonal projection to the principal surface 393 of the semiconductor layer 301, it can be said that regions of the principal surface 393 that are arranged between the respective portions 451 and are not covered with the electrode pattern 321 constitute at least part of the region 403. A structure in which the portions 451 having a longitudinal direction are arranged in the widthwise direction, like the electrode pattern 321 shown in FIG. 6, is sometimes called a comb-like structure.

To increase the area of the interface of the Schottky junction and improve the sensitivity to the long wavelength range such as the SWIR band, the width of the portion 451 of the electrode pattern 321 in the vertical direction may be equal to or smaller than the wavelength of received light and further, equal to or smaller than λ/10, and the portions 451 may be arranged in a predetermined period in the vertical direction. The portion 451 of the electrode pattern 321 has semi-transparency or transparency (transmittance of, for example, about 1 to 100%) with respect to the wavelength of received light. Typically, the width of the portion 451 of the electrode pattern 321 in the vertical direction may be equal to or smaller than 100 nm. For example, the portions 451 of the electrode pattern 321 may be arranged in a period of 100 nm or less. In this case, the width of the portion 451 of the electrode pattern 321 in the vertical direction becomes smaller than 100 nm.

In the orthogonal projection to the principal surface 393 of the semiconductor layer 301, when the pixel 101 is rectangular, as shown in FIG. 6, the shape of the electrode pattern 321 can be a rectangle in which the slits 421 are arranged. Conductive plugs 324 for supplying the potential VSB to the electrode pattern 321 are arranged at the periphery of the electrode pattern 321. The sealing layer 326 is arranged to cover the pinning layer 320 and the electrode pattern 321, and a light shielding layer 325 for suppressing stray light is arranged between the electrode pattern 321 and the light incident surface 395 inside the sealing layer 326. The light shielding layer 325 can be formed using a metal or the like. Openings 307 are arranged at portions of the light shielding layer 325 through which light enters. In the orthogonal projection to the principal surface 393 of the semiconductor layer 301, the openings 307 and the electrode pattern 321 are arranged to overlap each other. As shown in FIGS. 6 and 7, the light shielding layer 325 may serve as even a wiring pattern that supplies the potential VSB to the electrode pattern 321. The potential VSB is supplied to the light shielding layer 325 via a wiring pattern (not shown). Power is supplied from the light shielding layer 325 to the electrode pattern 321 via the conductive plugs 324, forming the depletion region 322 in the semiconductor region 306. In the orthogonal projection to the principal surface 393 of the semiconductor layer 301, the opening 307 may be smaller than a region defined by an imaginary line (the imaginary line represents an outer edge on the assumption that no slit 421 is arranged in the electrode pattern 321) connecting the outermost edges of the electrode pattern 321. For example, the principal surface 393 of the semiconductor layer 301 may have a region overlapping the opening 307 in the orthogonal projection to the principal surface 393, and the region overlapping the opening 307 may include a region in contact with the electrode pattern 321 and a region in contact with the insulating layer (pinning layer 320).

The microlens 330 is stacked on the sealing layer 326 on the side of the light incident surface 395. The microlens 330 is arranged at the center of the pixel 101 to collect incident light toward the electrode pattern 321. This can increase the quantity of light used for photoelectric conversion and improve the sensitivity of the photoelectric conversion device 100. Light entering from the light incident surface 395 is collected by the microlens 330, passes through the opening 307 arranged in the sealing layer 326 and the light shielding layer 325, and reaches the SBD 221 (electrode pattern 321 and depletion region 322) formed on the surface (principal surface 393) of the semiconductor region 306 constituting the semiconductor layer 301. The light arriving at the depletion region 322 generates charges. The charges are diffused inside the semiconductor region 306 of the semiconductor layer 301 by an electric field applied to the electrode pattern 321, and reach the semiconductor region 312 of the second conductivity type.

The potential VH is applied to the semiconductor region 311 of the first conductivity type functioning as the cathode of the avalanche multiplication region, and the potential VH is applied to the semiconductor region 313 of the first conductivity type. The potential VL is applied to the semiconductor region 315 of the second conductivity type functioning as the anode of the avalanche multiplication region, and the potential VL is applied to the semiconductor region 312 of the second conductivity type via the semiconductor region 314 of the second conductivity type. The avalanche multiplication region is formed in a region near the p-n junction surface 411 on which the semiconductor region 313 of the first conductivity type and the semiconductor region 312 of the second conductivity type contact each other. By supplying such potentials, when charges generated by incident light pass through the avalanche region, they cause avalanche multiplication, generating an avalanche current. Photoelectric conversion in the SBD 221 has been described above, but the photoelectric conversion is not limited to one arising from the SBD 221. The semiconductor region 306 functions as even the light absorption layer (depletion layer) of the APD 201. For example, charges arising from light of the visible light range absorbable by silicon are generated, and when passing through the avalanche region, cause avalanche multiplication, generating an avalanche current.

The semiconductor region 314 has a role of an isolation region between the adjacent pixels 101. The semiconductor region 315 of the second conductivity type is arranged to reduce a contact resistance between the semiconductor region 314 and a wiring pattern arranged in the wiring structure 302. In this case, the impurity concentration is higher in the semiconductor region 315 than in the semiconductor region 314. The impurity concentration means a net impurity concentration obtained by subtracting a compensation of an impurity of a reverse conductivity type. That is, the impurity concentration is a net doping concentration. A region where the p-type doped impurity concentration is higher than the n-type doped impurity concentration is a p-type semiconductor region. In contrast, a region where the n-type doped impurity concentration is higher than the p-type doped impurity concentration is a n-type semiconductor region.

The trench structure 316 is a groove or through hole provided in the semiconductor layer 301. The side wall of the trench structure 316 is covered with the semiconductor region 314. The trench structure 316 suppresses a crosstalk in which light in the pixel 101 enters the adjacent pixel 101. A pinning layer, an air gap, an insulating layer containing a dielectric, a layer containing an opaque material for light shielding, and the like can be arranged inside the trench structure 316. Silicon oxide or the like may be buried as the insulating layer containing a dielectric, or a metal or the like may be buried as the layer containing an opaque material for light shielding.

The circuit board 21 is constituted including the semiconductor layer 304 and the wiring structure 305. As part of the signal processing circuit 103, the above-described waveform shaping circuit 210, counter circuit 211, selection circuit 212, quench element 202, and the like can be arranged. The circuit board 21 functions as a readout circuit that monitors a potential level at the node A and outputs it as a detection signal by using an increase/decrease in avalanche multiplication current flowing through the quench element 202 by photoelectric conversion caused by incident photons. The circuit board 21 can generate imaging data based on signals output from the arrayed pixels 101. As described above, in the photoelectric conversion device 100 according to the embodiment, the SBD 221 is arranged on the back surface (principal surface 393) of the semiconductor layer 301 on which the APD 201 is arranged in the backside illumination stacked SPAD. This can improve not only miniaturization of the pixel 101 by stacking the photoelectric conversion element 102 and the signal processing circuit 103, but also the efficiency of photoelectric conversion in the long wavelength range such as the infrared range.

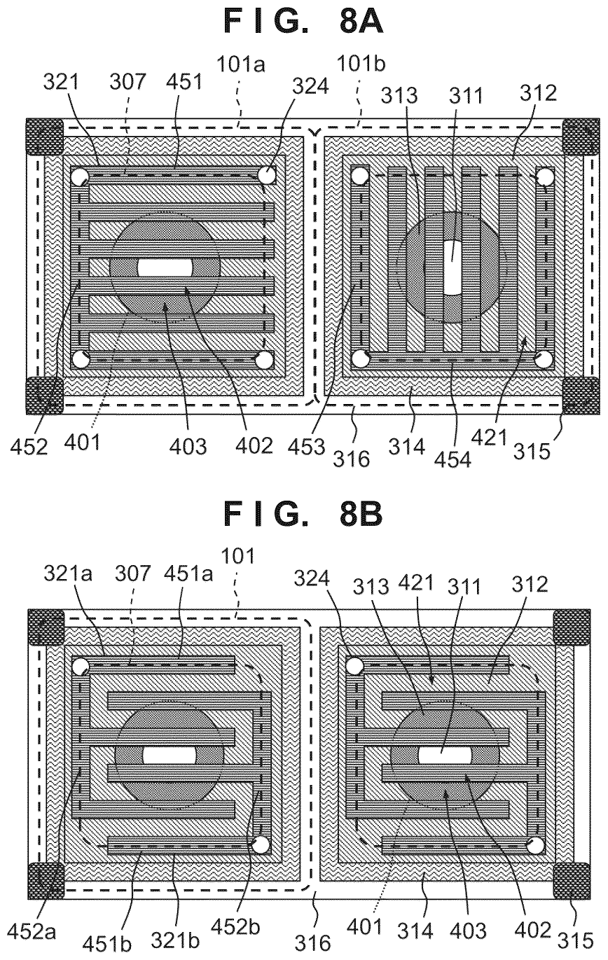

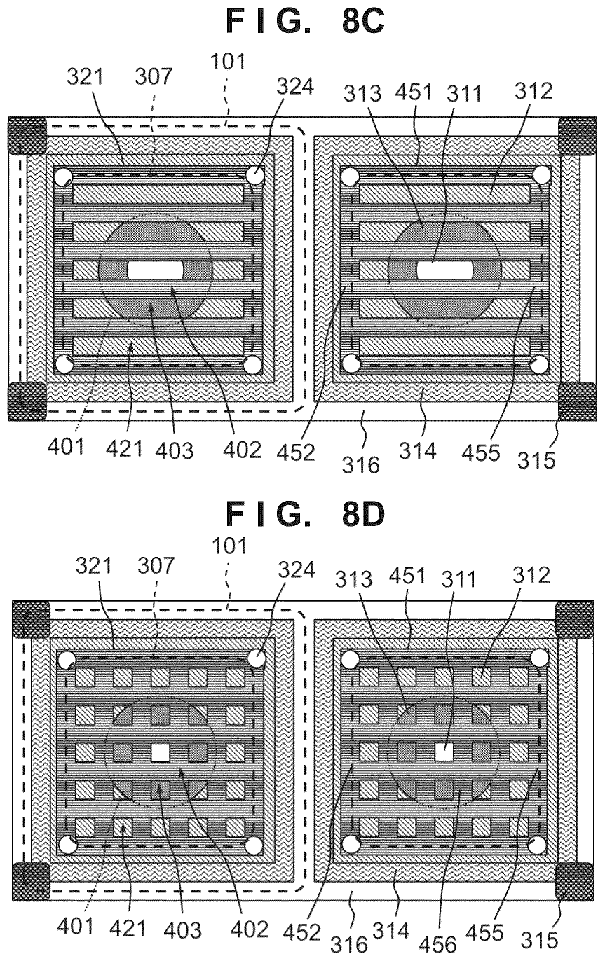

FIGS. 8A to 8D are views showing modifications of the electrode pattern 321 shown in FIG. 6. Other than the shape of the electrode pattern 321, arrangements can be similar to the above-described ones. Thus, a description of arrangements except the shape of the electrode pattern 321 will be omitted properly.

FIG. 8A shows an example in which the electrode patterns 321 constituted by rotating the slits 421 by 90° are arranged in adjacent pixels 101a and 101b. In an orthogonal projection to the principal surface 393 of the semiconductor layer 301, the electrode pattern 321 of the pixel 101a has a lateral direction in FIG. 8A as a longitudinal direction, and includes the plurality of portions 451 arranged to align in a vertical direction intersecting the lateral direction, and the portion 452 arranged in the vertical direction so as to connect ends of the portions 451 to each other on one side in the lateral direction. In the pixel 101a, regions of the principal surface 393 of the semiconductor layer 301 that are arranged between the respective portions 451 and are not covered with the electrode pattern 321 constitute at least part of the above-described region 403. In contrast, in the orthogonal projection to the principal surface 393 of the semiconductor layer 301, the electrode pattern 321 of the pixel 101b has the vertical direction in FIG. 8A as a longitudinal direction, and includes a plurality of portions 453 arranged to align in the lateral direction, and a portion 454 arranged in the lateral direction so as to connect ends of the portions 453 to each other on one side in the vertical direction. In the pixel 101b, regions of the principal surface 393 of the semiconductor layer 301 that are arranged between the respective portions 453 and are not covered with the electrode pattern 321 constitute at least part of the above-described region 403. The angle by which the electrode pattern 321 is rotated is not limited to 90°, and may be properly selected in accordance with the deflection direction of received light. The structure shown in FIG. 8A enables the pixels 101a and 101b to receive beams in different deflection directions. For example, when the photoelectric conversion device 100 is applied to a system intentionally utilizing deflection, information of differently deflected beams can be obtained.

FIG. 8B shows an example in which two electrode patterns 321a and 321b are arranged in one pixel 101. In an orthogonal projection to the principal surface 393 of the semiconductor layer 301, the electrode pattern 321a has a lateral direction in FIG. 8B as a longitudinal direction, and includes a plurality of portions 451a arranged to align in a vertical direction intersecting the lateral direction, and a portion 452a arranged in the vertical direction so as to connect ends of the portions 451a to each other on one side in the lateral direction. In the orthogonal projection to the principal surface 393 of the semiconductor layer 301, the electrode pattern 321b has the lateral direction as a longitudinal direction, and includes a plurality of portions 451b arranged to align in the vertical direction, and a portion 452b arranged in the vertical direction so as to connect ends of the portions 451b to each other on one side in the lateral direction. Regions of the principal surface 393 of the semiconductor layer 301 that are arranged between the respective portions 451a and 451b and are not covered with the electrode patterns 321a and 321b constitute at least part of the above-described region 403. The portions 451a and the portions 451b do not contact each other. As shown in FIG. 8B, the portions 451a and the portions 451b are alternately arranged in the vertical direction.

In the arrangement shown in FIG. 8B, two electrode patterns 321 are arranged in one pixel 101. However, the present invention is not limited to this, and three or more electrode patterns 321 may be arranged. With the structure shown in FIG. 8B, a plurality of electrode patterns 321 are arranged in one pixel 101, and an electric conductor of a different type can be selected for each electrode pattern 321. For example, the electrode patterns 321a and 321b contain different materials. By selectively using the material of the above-mentioned electrode pattern 321, the wavelength range of light receivable by one pixel 101 can be widened to improve the sensitivity.

FIG. 8C shows an example in which the slits 421 arranged in the electrode pattern 321 are surrounded by the electrode pattern 321. That is, in an orthogonal projection to the principal surface 393 of the semiconductor layer 301, the electrode pattern 321 further includes, in the arrangement shown in FIG. 6, a portion 455 arranged in the vertical direction so as to connect ends of the portions 451 to each other on the other side (side opposite to the side on which the portion 452 is arranged) in the lateral direction. In some cases, the electrode pattern 321 is a thin film of about 100 nm and has high resistance, and a voltage drop in the electrode pattern 321 changes depending on the location owing to the layout pattern of the slits 421 or the like. An increase in the resistivity of the electrode pattern 321 may cause a decrease in sensitivity and noise. The structure shown in FIG. 8C can suppress the distribution of a voltage drop of the electrode pattern 321. This can suppress a decrease in sensitivity and noise.

The arrangement shown in FIG. 8B or 8C and the arrangement shown in FIG. 8A in which the longitudinal direction of the portion 451 of the electrode pattern 321 differs depending on the pixel 101 may be combined. The effects described with reference to FIG. 8B or 8C and those described with reference to FIG. 8A can be combined and applied.

In the arrangements shown in FIGS. 8A to 8C, the slits 421 are arranged in the electrode pattern 321 so as to align in the vertical or lateral direction. However, the present invention is not limited to this. FIG. 8D shows an example in which the slits 421 are arranged in a two-dimensional array in the electrode pattern 321. That is, in an orthogonal projection to the principal surface 393 of the semiconductor layer 301, the electrode pattern 321 further includes, in the arrangement shown in FIG. 8C, one or more portions 456 that are arranged between the portions 452 and 455 and arranged in the vertical direction so as to connect the portions 451 to each other.

The aspect ratio of the slit 421 may be, for example, 1:1 (square). The slits 421 of the same shape may be periodically arranged. The periodic structure of the slits 421 may be symmetrical with respect to the diagonal line of the electrode pattern 321. The slit 421 is not limited to the square shape, but may be a circular shape, an oval shape, or a polygonal shape such as a triangle or more. The structure shown in FIG. 8D can suppress the influence of a decrease in sensitivity on polarization. The influence of the field direction generated at the edge of the slit 421 is reduced by adapting a polygonal shape as the slit 421, and the influence of a decrease in sensitivity on polarization can be further suppressed.

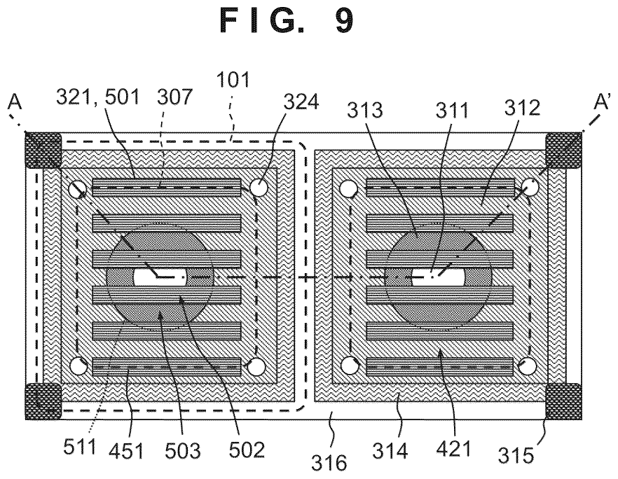

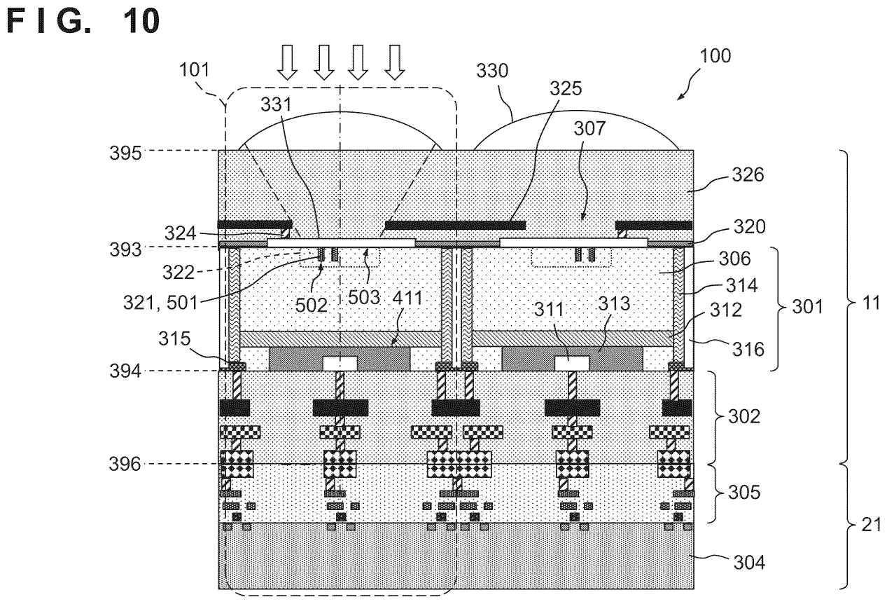

FIGS. 9 and 10 are views showing modifications of the above-described photoelectric conversion device 100. FIG. 9 is a plan view (orthogonal projection view) showing the arrangement of the pixel 101 arranged in the pixel region 12. FIG. 10 is a sectional view between A-A′ in FIG. 9. In the above embodiment, the arrangement in which the principal surface 393 of the semiconductor layer 301 is flat and the electrode pattern 321 is arranged on the flat principal surface 393 has been described. However, the arrangement of the electrode pattern 321 for constituting the SBD 221 is not limited to this. As shown in FIGS. 9 and 10, a plurality of recesses 501 may be arranged on the principal surface 393 of the semiconductor layer 301, and the electrode pattern 321 may be arranged in the recesses 501. A difference from the above-described arrangement will be mainly explained, and a description of a similar arrangement will be omitted properly.

As shown in FIGS. 9 and 10, the electrode pattern 321 has a lateral direction in FIG. 10 as a longitudinal direction, and includes the plurality of portions 451 arranged to align in a vertical direction intersecting the lateral direction in an orthogonal projection to the principal surface 393 of the semiconductor layer 301, similar to the above-described embodiment. The slits 421 are arranged between the respective portions 451. With this structure, light entering the photoelectric conversion device 100 enters the semiconductor region 306 of the semiconductor layer 301. The principal surface 393 of the semiconductor layer 301 has a region 511 overlapping the APD 201 in the orthogonal projection to the principal surface 393. The region 511 includes a region 502 where the recesses 501 (electrode pattern 321) are arranged, and a region 503 where the recesses 501 (electrode pattern 321) are not arranged. The region overlapping the APD 201 of the principal surface 393 of the semiconductor layer 301 is similar to the region described with reference to FIGS. 6 and 7. For example, the region overlapping the APD 201 may be a region overlapping the p-n junction surface 411 in the orthogonal projection to the principal surface 393 of the semiconductor layer 301. The region 511 in FIG. 9 represents a region overlapping the p-n junction surface 411.

As shown in FIG. 10, the electrode pattern 321 is buried in the recesses 501 provided in the principal surface 393 of the semiconductor layer 301. It can be said that the electrode pattern 321 is buried in the semiconductor region 306. The electrode pattern 321 and the semiconductor region 306 form a Schottky junction. The respective portions 451 of the electrode pattern 321 are connected to each other by a conductive layer 331 in contact with a region 503 where the portion 451 (electrode pattern 321) and the recess 501 of the principal surface 393 of the semiconductor layer 301 are not provided. The conductive layer 331 is electrically connected to the light shielding layer 325 via the conductive plug 324, and the potential VSB can be applied to the electrode pattern 321. The conductive layer 331 contacts the region 503 of the principal surface 393 of the semiconductor layer 301. Hence, a Schottky junction may be formed between the conductive layer 331 and the semiconductor layer 301 (semiconductor region 306). For the electrode pattern 321 and the conductive layer 331, the above-mentioned metal materials, silicides, conductive metal oxides, and the like are available. For example, a material opaque to the wavelength of received light can be used for the electrode pattern 321. Charges are generated by photoelectric conversion of light entering the Schottky junction interface between the conductive layer 331 and the semiconductor layer 301 (semiconductor region 306). The conductive layer 331 may be semi-transparent or transparent (light transmittance of, for example, about 1 to 100%) at the wavelength of received light. Therefore, the thickness of the conductive layer 331 may be equal to or smaller than the wavelength λ of received light and further, equal to or smaller than λ/10.

In the arrangement shown in FIG. 10, the electrode pattern 321 is buried in the semiconductor region 306. The Schottky junction is formed not only on the bottom surface but also on the side surface of the electrode pattern 321, and light can be received in a wider area than in a case where the electrode pattern 321 is arranged on the principal surface 393 of the flat semiconductor layer 301. Light entering from the light incident surface 395 can be easily guided into the semiconductor region 306, improving the sensitivity.

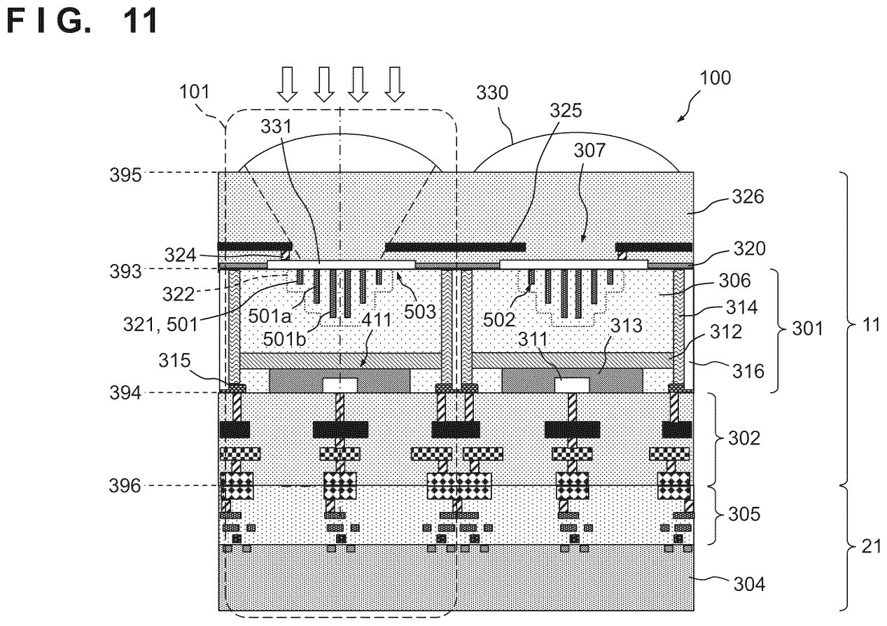

FIG. 11 is a view showing a modification of the sectional structure shown in FIG. 10. The recesses 501 in which the electrode pattern 321 is buried may include recesses 501 of different depths. The depth here is a length from the principal surface 393 of the semiconductor layer 301. A direction close to the principal surface 394 is a deep direction, and a direction close to the principal surface 393 is a shallow direction.

Light entering from the principal surface 393 of the semiconductor layer 301 can enter the inside of the semiconductor region 306 while repetitively reflected between the side surfaces of the electrode pattern 321 (portions 451). The light entering the photoelectric conversion device 100 is collected by the microlens 330, so the light quantity increases toward the center from the outer edge of the pixel 101. At the center of the pixel 101, light can enter a deep position in the semiconductor region 306. Thus, a recess 501b arranged closer to the center of the pixel 101 than a recess 501a may be formed deeper than the recess 501a. The electrode pattern 321 is also buried deep in the recess 501b. This enables effectively using light entering up to a deep portion at the center of the semiconductor region 306, and improving the sensitivity. The area of contact between the electrode pattern 321 and the principal surface 393 (semiconductor region 306) of the semiconductor layer 301 can be optimized to suppress unwanted noise and improve the S/N ratio.

In the orthogonal projection to the principal surface 393 of the semiconductor layer 301, the shape of the electrode pattern 321 buried in the semiconductor region 306 is not limited to the shape shown in FIG. 9. The respective shapes shown in FIG. 6 and FIGS. 8A to 8D may be applied.

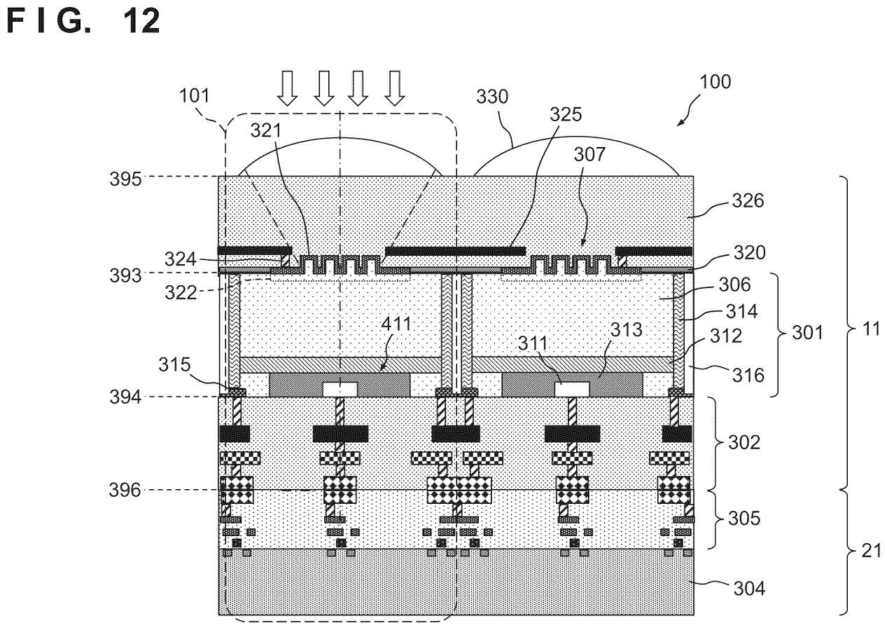

FIG. 12 is a view showing a modification of the above-described photoelectric conversion device 100. In the above-described embodiment, the slits 421 are arranged in the electrode pattern 321. However, the present invention is not limited to this. As for a structure shown in FIG. 12, a difference from the above-described embodiment will be mainly explained.

In the structure shown in FIG. 12, similar to the structure according to the above-described embodiment, each of the pixels 101 includes the APD 201 arranged in the semiconductor layer 301, and the SBD 221 constituted by the semiconductor layer 301 and the electrode pattern 321 in contact with the principal surface 393 of the semiconductor layer 301. However, unlike the above-described embodiment, the principal surface 393 of the semiconductor layer 301 has a periodic concave-convex structure, and the electrode pattern 321 is arranged to cover the principal surface 393 of the semiconductor layer 301 having the concave-convex structure. That is, the slits 421 are not arranged.

FIG. 12 shows an example of a comb-like structure in which a depth direction in FIG. 12 is set as a longitudinal direction, and concave portions and convex portions are repetitively arranged as the concave-convex structure so as to align in a lateral direction intersecting the depth direction in an orthogonal projection to the principal surface 393 of the semiconductor layer 301. However, the periodic concave-convex structure is not limited to this. For example, pyramid structures or hole structures may be periodically arrayed to engrave the semiconductor region 306 on the principal surface 393 of the semiconductor layer 301. Alternatively, pyramid structures or pillar structures may be periodically arrayed to project from the principal surface 393 of the semiconductor layer 301. That is, the concave-convex structure may include a plurality of convex portions or a plurality of concave portions arranged two-dimensionally in the orthogonal projection to the principal surface 393 of the semiconductor layer 301.

Such a periodic concave-convex structure may have such a period and width that light entering the electrode pattern 321 causes localized plasmon resonance. That is, the structure shown in FIG. 12 may be formed by a design compliant with a specific wavelength among wavelengths of received light.

An example of a more concrete concave-convex structure will be explained. A comb-like concave-convex structure as shown in FIG. 12 was formed. Gold (Au) was used for the electrode pattern 321. In the comb-like structure, the period in the lateral direction shown in FIG. 12 was 265 nm, the width of the convex portion (comb) was 230 nm, and the film thickness of the electrode pattern 321 was 10 nm. A 15-nm gap remains between the convex portions (concave portions). FIG. 13 shows an absorption spectrum in this case.

As shown in FIG. 13, silicon has a low absorption coefficient on the long wavelength side and becomes poor in sensitivity to the long wavelength range. To solve this, a comb-like concave-convex structure is provided on the principal surface 393 of the semiconductor layer 301 using silicon, and the electrode pattern 321 using gold is arranged. In this case, the concave-convex structure has such periodicity as to cause localized plasmon resonance with respect to light in the long wavelength range such as infrared light. Light can therefore be absorbed even in the long wavelength range, as shown in FIG. 13.

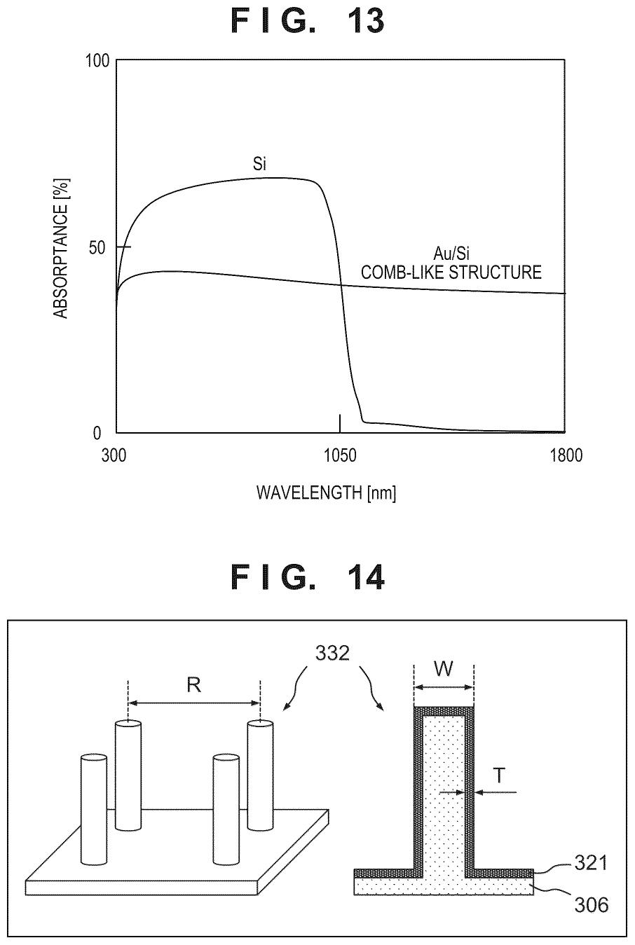

FIG. 14 is a view for explaining, as the periodic concave-convex structure, a nano-pillar structure in which a plurality of pillar structures 332 are periodically arranged. For example, an interval R between the pillar structures 332 is set to be 1 μm, a width (diameter) W including the thickness of the electrode pattern 321 of the pillar structure 332 is set to be about 375 to 500 nm, and the film thickness of the electrode pattern 321 is set to be 20 to 30 nm. With this setting, light in the long wavelength range can be absorbed in comparison with silicon.

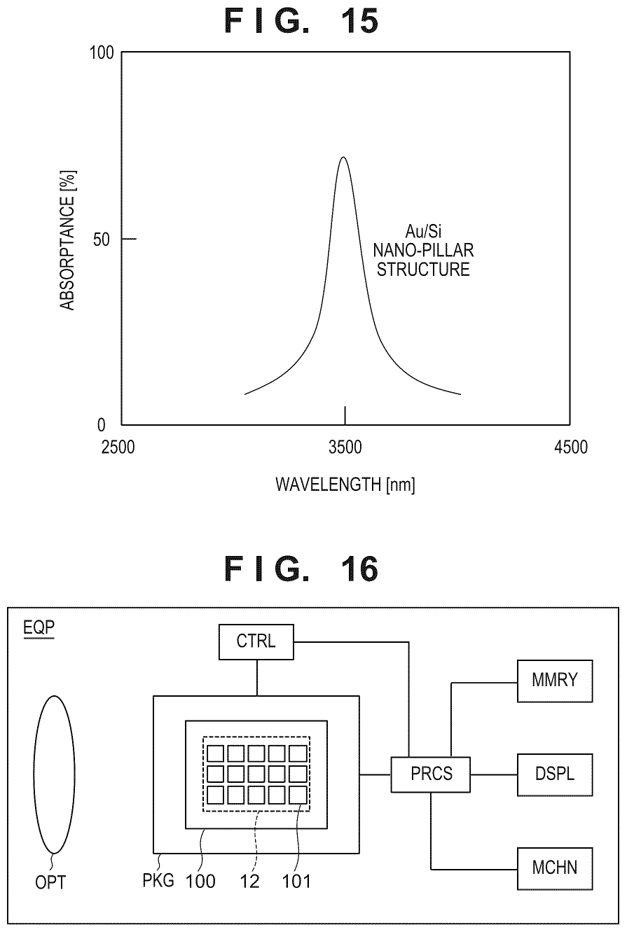

An example of a concrete concave-convex structure will be explained. Gold (Au) of 20 nm was used for the electrode pattern 321. The interval R between the pillar structures 332 was set to be 1 μm, and the width W was set to be 500 nm. FIG. 15 shows an absorption spectrum in this case. As shown in FIG. 15, a steep absorption characteristic was obtained for light in the infrared range at a wavelength of about 3,500 nm. The wavelength range of absorbed light can be adjusted by the interval R between the pillar structures 332, the width W, and the thickness and material of the electrode pattern 321.

The characteristic as shown in FIG. 13 is a broad absorption characteristic from visible light to the infrared range, and can be applied to an application requiring sensitivity to a wide band. This characteristic may be used in, for example, a surveillance camera or the like. On the other hand, the characteristic as shown in FIG. 15 has a high absorptance near a specific wavelength and a low absorptance in the remaining wavelength range, and can improve the S/N ratio. The characteristic shown in FIG. 15 can be applied to an application that detects light of a specific wavelength, such as biofluorescence imaging for observing fluorescence emission.

An application example of the photoelectric conversion device 100 according to the embodiment described above will be described below. FIG. 16 is a schematic view of an electronic equipment EQP incorporating the photoelectric conversion device 100. FIG. 16 shows a camera as an example of the electronic equipment EQP. The concept of a camera here not only includes an apparatus whose main object is image capturing, but also an apparatus (for example, a personal computer or a mobile terminal such as a smartphone) that has an image capturing function auxiliarly.

The photoelectric conversion device 100 can be a semiconductor chip with a stacked structure including the pixel region 12 in which the pixels 101 are arranged. As shown in FIG. 16, the photoelectric conversion device 100 is contained in a semiconductor package PKG. The semiconductor package PKG can include a base to which the photoelectric conversion device 100 is fixed, a lid such as glass facing the photoelectric conversion device 100, and a conductive connecting member such as a bonding wire or bump used to connect the terminal arranged in the base to a terminal arranged in the photoelectric conversion device 100. The equipment EQP may further include at least one of an optical system OPT, a control device CTRL, a processing device PRCS, a display device DSPL, and a storage device MMRY.

The optical system OPT is a system for forming an image on the photoelectric conversion device 100, and can be, for example, a lens, a shutter, and a mirror. The control device CTRL is a device for controlling the operation of the photoelectric conversion device 100, and can be, for example, a semiconductor device such as an ASIC or the like. The processing device PRCS processes the signal output from the photoelectric conversion device 100, and can be, for example, a semiconductor device such as a CPU, an ASIC, or the like. The display device DSPL can be an EL display device or a liquid crystal display device that displays image data obtained by the photoelectric conversion device 100. The storage device MMRY is a magnetic device or a semiconductor device for storing the image data obtained by the photoelectric conversion device 100. The storage device MMRY can be a volatile memory such as an SRAM, a DRAM, or the like or a nonvolatile memory such as a flash memory or a hard disk drive. A mechanical device MCHN includes a moving or propulsion unit such as a motor or an engine. The mechanical device MCHN in the camera can drive the components of the optical system OPT for zooming, focusing, and shutter operations. In the equipment EQP, image data output from the photoelectric conversion device 100 is displayed on the display device DSPL, or transmitted to an external device by a communication device (not shown) included in the equipment EQP. Hence, the equipment EQP may also include the storage device MMRY and the processing device PRCS.

The camera incorporating the photoelectric conversion device 100 is also applicable as a surveillance camera or an onboard camera mounted in a transportation equipment such as an automobile, a railroad car, a ship, an airplane, or an industrial robot. In addition, the camera incorporating the photoelectric conversion device 100 is not limited to a transportation equipment but is also applicable to an equipment that widely uses object recognition, such as an intelligent transportation system (ITS).

The present invention can provide a technique advantageous for improving the sensitivity to the long wavelength range.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-083186, filed May 19, 2023, which is hereby incorporated by reference herein in its entirety.

What is claimed is:

1. A photoelectric conversion device in which a plurality of pixels are arranged in a semiconductor layer having a first principal surface and a second principal surface,
wherein each of the plurality of pixels comprises:
an avalanche photodiode arranged in the semiconductor layer; and
a Schottky barrier diode constituted by the semiconductor layer and an electrode pattern in contact with the second principal surface,
in an orthogonal projection to the second principal surface, the second principal surface has a region overlapping the avalanche photodiode, and
the region includes a first region in contact with the electrode pattern and a second region in contact with an insulating layer.

2. The device according to claim 1, wherein in the orthogonal projection to the second principal surface, the electrode pattern has a slit, and
the slit constitutes the second region.

3. The device according to claim 1, wherein in the orthogonal projection to the second principal surface, the electrode pattern has a first direction as a longitudinal direction, and includes a plurality of first portions arranged to align in a second direction intersecting the first direction, and a second portion arranged in the second direction to connect ends of the plurality of first portions to each other on one side in the first direction, and
in the orthogonal projection to the second principal surface, regions of the second principal surface that are arranged between the respective first portions and are not covered with the electrode pattern constitute at least part of the second region.

4. The device according to claim 3, wherein in the orthogonal projection to the second principal surface, the electrode pattern further includes a third portion arranged in the second direction to connect ends of the plurality of first portions to each other on another side in the first direction.

5. The device according to claim 4, wherein in the orthogonal projection to the second principal surface, the electrode pattern further includes at least one fourth portion arranged between the second portion and the third portion and arranged in the second direction to connect the plurality of first portions to each other.

6. The device according to claim 1, wherein the plurality of pixels include a first pixel and a second pixel,
in the orthogonal projection to the second principal surface,
the electrode pattern of the first pixel has a first direction as a longitudinal direction, and includes a plurality of first portions arranged to align in a second direction intersecting the first direction, and a second portion arranged in the second direction to connect ends of the plurality of first portions to each other on one side in the first direction,
in the first pixel, regions of the second principal surface that are arranged between the respective first portions and are not covered with the electrode pattern constitute at least part of the second region,
the electrode pattern of the second pixel has the second direction as a longitudinal direction, and includes a plurality of third portions arranged to align in the first direction, and a fourth portion arranged in the first direction to connect ends of the plurality of third portions to each other on one side in the second direction, and
in the second pixel, regions of the second principal surface that are arranged between the respective third portions and are not covered with the electrode pattern constitute at least part of the second region.

7. The device according to claim 6, wherein the first pixel and the second pixel are arranged to be adjacent to each other.

8. The device according to claim 1, wherein the electrode pattern includes a first electrode pattern and a second electrode pattern,
in the orthogonal projection to the second principal surface,
the first electrode pattern has a first direction as a longitudinal direction, and includes a plurality of first portions arranged to align in a second direction intersecting the first direction, and a second portion arranged in the second direction to connect ends of the plurality of first portions to each other on one side in the first direction,
the second electrode pattern has the first direction as a longitudinal direction, and includes a plurality of third portions arranged to align in the second direction, and a fourth portion arranged in the second direction to connect ends of the plurality of third portions to each other on the other side in the first direction, and
regions of the second principal surface that are arranged between the respective first portions and the respective third portions and are not covered with the first electrode pattern and the second electrode pattern constitute at least part of the second region.

9. The device according to claim 8, wherein the plurality of first portions and the plurality of third portions do not contact each other.

10. The device according to claim 8, wherein the first electrode pattern and the second electrode pattern contain different materials from each other.

11. The device according to claim 8, wherein the plurality of first portions and the plurality of third portions are alternately arranged in the second direction.

12. A photoelectric conversion device in which a plurality of pixels are arranged in a semiconductor layer having a first principal surface and a second principal surface,
wherein each of the plurality of pixels comprises:
an avalanche photodiode arranged in the semiconductor layer; and
a Schottky barrier diode constituted by the semiconductor layer and an electrode pattern in contact with the second principal surface,
a plurality of recesses in which the electrode pattern is buried are provided on the second principal surface,
in an orthogonal projection to the second principal surface, the second principal surface has a region overlapping the avalanche photodiode, and
the region includes a first region where the plurality of recesses are arranged, and a second region where the plurality of recesses are not arranged.

13. The device according to claim 12, wherein the plurality of recesses include recesses of different depths.

14. The device according to claim 13, wherein the plurality of recesses include a first recess and a second recess arranged closer to a center of the pixel than the first recess, and
the second recess is deeper than the first recess.

15. The device according to claim 12, wherein in the orthogonal projection to the second principal surface, the electrode pattern has a first direction as a longitudinal direction, and includes a plurality of first portions arranged to align in a second direction intersecting the first direction, and
the plurality of first portions are connected to each other by a conductive layer in contact with the plurality of first portions and the second region.

16. The device according to claim 3, wherein a width of each of the plurality of first portions in the second direction is not larger than 100 nm.

17. The device according to claim 3, wherein the plurality of first portions are arranged in the second direction in a predetermined period.

18. The device according to claim 17, wherein the predetermined period is not larger than 100 nm.

19. A photoelectric conversion device in which a plurality of pixels are arranged in a semiconductor layer having a first principal surface and a second principal surface,
wherein each of the plurality of pixels comprises:
an avalanche photodiode arranged in the semiconductor layer; and
a Schottky barrier diode constituted by the semiconductor layer and an electrode pattern in contact with the second principal surface to cover the second principal surface, and
the second principal surface has a periodic concave-convex structure.

20. The device according to claim 19, wherein in an orthogonal projection to the second principal surface, a first direction is set as a longitudinal direction, and concave portions and convex portions are arranged as the concave-convex structure to align in a second direction intersecting the first direction.

21. The device according to claim 19, wherein in an orthogonal projection to the second principal surface, the concave-convex structure includes a plurality of convex portions or a plurality of concave portions arranged two-dimensionally.

22. The device according to claim 19, wherein the concave-convex structure has periodicity to cause localized plasmon resonance with respect to infrared light.

23. The device according to claim 1, wherein in the orthogonal projection to the second principal surface, the Schottky barrier diode is arranged to overlap the avalanche photodiode.

24. Equipment comprising:
the photoelectric conversion device according to claim 1; and
a processor configured to process a signal output from the photoelectric conversion device.
